(19) United States
(12) Patent Application Publication
(10) Pub. No.: US 2002/0030801 A1
(43) Pub. Date: Mar. 14, 2002

(54) Electron beam aligner, outgassing collection method and gas analysis method

(76) Inventors: Masayuki Endo, Izumi-shi (JP); Masaru Sasago, Hirakata-shi (JP)

Correspondence Address: NIXON PEABODY, LLP, 8180 GREENSBORO DRIVE, SUITE 800, MCLEAN, VA, 22102, US

(21) Appl. No.: 09/921,921

(22) Filed: Aug. 6, 2001

(30) Foreign Application Priority Data
Sep. 14, 2000 (JP) 2000-279295

(51) Int. Cl. H01L 21/66; G01R 31/26

(52) U.S. Cl. 355/53; 438/14

(57) ABSTRACT

An electron beam aligner includes a substrate holder provided within a chamber for holding a semiconductor substrate on a surface of which a resist film is formed; and an electron beam source for fully irradiating the resist film with an electron beam. The chamber is provided with a gas collection member for collecting an outgassing released from the resist film when irradiated with the electron beam.

### BACKGROUND OF THE INVENTION

The present invention relates to an electron beam aligner, an outgassing collection method and a gas analysis method for use in electron beam lithography of the fabrication process for a semiconductor device.

In accordance with refinement of semiconductor devices included in semiconductor integrated circuits, there are increasing demands for further refinement of interconnect patterns. In order to obtain further finer patterns, use of light of a wavelength shorter than that of conventionally used UV, such as an electron beam, as the exposing light is now being examined.

In the electron beam lithography, that is, a technique to form a resist pattern by irradiating a resist film with an electron beam emitted from an electron source, an electron beam projection exposure method (for example, H. C. Pfeiffer et al., J. Vac. Sci. Technol., B17(6), 2840 (1999)) that is good in the throughput and resolution is regarded as a promising method. Since energy of high acceleration of approximately 100 keV is generally used in this projection exposure method, electrons are less forward scattered, resulting in attaining high resolution.

However, when a resist film is irradiated with an electron beam, an outgassing (that is, a gas released from the resist film owing to an outgassingsing phenomenon occurring in the resist film) is generated from the resist film, and the outgassing absorbs the energy of the electron beam. As a result, the energy of the electron beam is disadvantageously varied.

In lithography using a F₂ laser beam, an outgassing is measured and analyzed because the outgassing generated from a resist film can damage an optical system of an aligner (for example, R. R. Kunz et al., J. Vac. Sci. Technol., B17(6), 3330 (1999)).

On the contrary, in the electron beam lithography, there is no device for qualitatively or quantitatively measuring the influence of an outgassing generated from a resist film.

This is because, in the exposure method using a general electron beam lithography system, a very long exposure time is unpractically required for collecting a gas necessary for the gas chromatography analysis. Also, the electron beam lithography system is structurally difficult to include a gas collecting pipe for collecting an outgassing and a gas analyzer for analyzing the outgassing, and hence, an electron beam lithography system equipped with a gas collecting pipe and a gas analyzer has not been realized.

With respect to an electron beam aligner corresponding to the subject of the present invention, namely, an apparatus for fully irradiating a resist film with an electron beam, although a device capable of measuring material change of a resist film through the irradiation with an electron beam has been proposed, an electron beam aligner equipped with a device for collecting an outgassing generated from a resist film or a device for analyzing an outgassing has not been proposed yet.

Accordingly, in an electron beam aligner, an outgassing generated from a resist film can be neither collected nor analyzed at present.

### SUMMARY OF THE INVENTION

In consideration of the aforementioned circumstances, a first object of the invention is, in an electron beam aligner for fully irradiating a resist film with an electron beam, collecting an outgassing generated from the resist film, and a second object is analyzing an outgassing generated from the resist film.

In order to achieve the first object, the first electron beam aligner of this invention comprises a substrate holder provided within a chamber for holding a semiconductor substrate on a surface of which a resist film is formed; electron beam irradiation means for fully irradiating the resist film with an electron beam; and gas collection means provided on the chamber for collecting an outgassing released from the resist film when irradiated with the electron beam.

Since the first electron beam aligner of this invention includes the gas collection means for collecting the outgassing released from the resist film when irradiated with the electron beam, the outgassing released from the resist film when the resist film is fully irradiated with the electron beam in the electron beam aligner can be collected by the gas collection means.

The first electron beam aligner preferably further comprises gas analysis means for analyzing a constituent of the outgassing collected by the gas collection means.

In this manner, the constituent of the outgassing collected by the gas collection means can be qualitatively or quantitatively analyzed.

In order to achieve the second object, the second electron beam aligner of this invention comprises a substrate holder provided within a chamber for holding a semiconductor substrate on a surface of which a resist film is formed; electron beam irradiation means for fully irradiating the resist film with an electron beam; and gas analysis means provided on the chamber for analyzing a constituent of an outgassing released from the resist film when irradiated with the electron beam.

Since the second electron beam aligner of this invention includes the gas analysis means for analyzing the constituent of the outgassing released from the resist film when irradiated with the electron beam, the constituent of the outgassing released from the resist film when the resist film is fully irradiated with the electron beam in the electron beam aligner can be qualitatively or quantitatively analyzed.

In order to achieve the first object, the outgassing collection method of this invention comprises the steps of holding, within a chamber, a semiconductor substrate on a surface of which a resist film is formed; fully irradiating the resist film with an electron beam; and collecting an outgassing released from the resist film when irradiated with the electron beam.

In the outgassing collection method of this invention, the outgassing released from the resist film when fully irradiated with the electron beam can be collected.

In order to achieve the second object, the first outgassing analysis method of this invention comprises the steps of holding, within a chamber, a semiconductor substrate on a surface of which a resist film is formed; fully irradiating the resist film with an electron beam; collecting an outgassing released from the resist film when irradiated with the electron beam; and analyzing a constituent of the collected outgassing.

In the first outgassing analysis method of this invention, the outgassing released from the resist film when irradiated with the electron beam can be collected and the constituent of the outgassing can be qualitatively or quantitatively analyzed.

In order to achieve the second object, the second outgassing analysis method of this invention comprises the steps of holding, within a chamber, a semiconductor substrate on a surface of which a resist film is formed; fully irradiating the resist film with an electron beam; and analyzing a constituent of an outgassing released from the resist film when irradiated with the electron beam.

In the second outgassing analysis method, the constituent of the outgassing released from the resist film when irradiated with the electron beam can be qualitatively or quantitatively analyzed.

### BRIEF DESCRIPTION OF THE DRAWINGS

FIG. 1 is a cross-sectional view of an electron beam aligner according to Embodiment 1 of the invention; and

FIG. 2 is a cross-sectional view of an electron beam aligner according to Embodiment 2 of the invention.

### DETAILED DESCRIPTION OF THE INVENTION

Embodiment 1

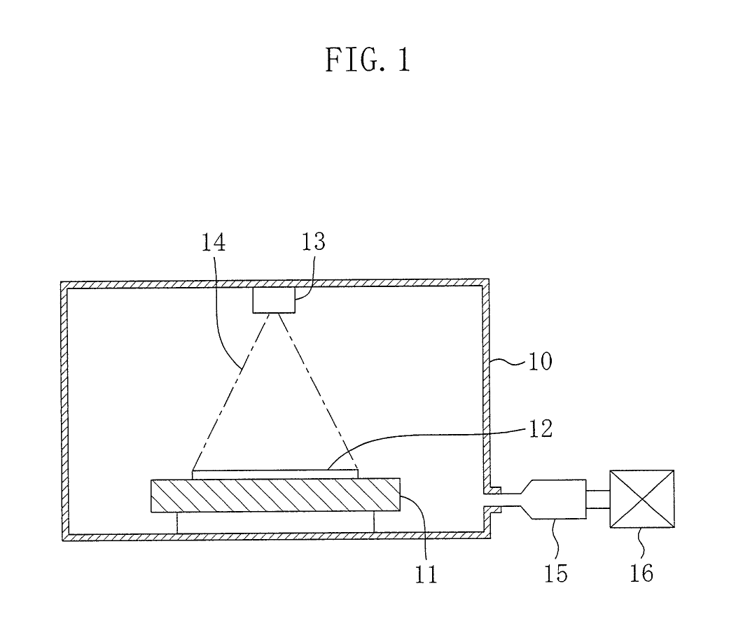

An electron beam aligner, an outgassing collection method and a gas analysis method according to Embodiment 1 of the invention will now be described with reference to FIG. 1.

As shown in FIG. 1, on the bottom of an evacuated chamber 10, a stage 11 serving as a substrate holder is provided, and the stage 11 holds a semiconductor substrate 12 on the surface of which a resist film is formed. The kind and the thickness of the resist film are not particularly specified, and for example, a resist film with a thickness of 0.7 μm may be formed from a chemically amplified resist.

On the ceiling of the chamber 10, namely, on a portion opposing the stage 11, an electron beam source 13 serving as electron beam irradiation means is provided, and the electron beam source 13 fully irradiates the resist film formed on the semiconductor substrate 12 with an electron beam 14 of, for example, 10 keV over five minutes.

On a side of the chamber 10, a gas collection pipe 15 serving as gas collection means is provided, and the gas collection pipe 15 contains, for example, activated carbon. Accordingly, when the electron beam source 13 irradiates the resist film on the semiconductor substrate 12, an outgassing released from the resist film is adsorbed by the activated carbon contained in the gas collection pipe 15. Also, when the gas collection pipe 15 is heated to a temperature of, for example, approximately 400° C., the outgassing is released from the activated carbon.

On the side of the gas collection pipe 15 opposite the chamber 10, a gas chromatograph mass spectrometer (GC-MS) 16 serving as gas analysis means for analyzing the outgassing collected in the gas collection pipe 15 is provided. Thus, the gas chromatograph mass spectrometer 16 can quantitatively or qualitatively analyze a constituent of the outgassing, such as isobutene that is the principal constituent, released from the activated carbon contained in the gas collection pipe 15.

Embodiment 2

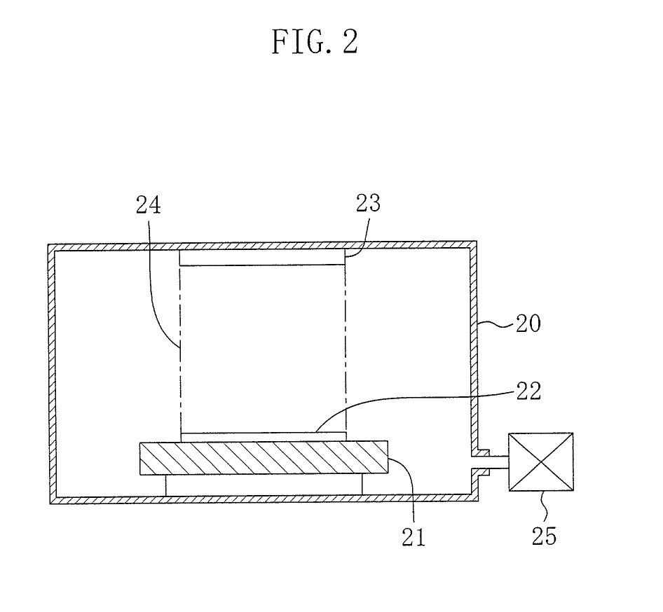

An electron beam aligner and a gas analysis method according to Embodiment 2 of the invention will now be described with reference to FIG. 2.

As shown in FIG. 2, on the bottom of an evacuated chamber 20, a stage 21 serving as a substrate holder is provided, and the stage 21 holds a semiconductor substrate 22 on the surface of which a resist film is formed. The kind and the thickness of the resist film are not particularly specified, and for example, a resist film with a thickness of 0.7 μm may be formed from a chemically amplified resist.

On the ceiling of the chamber 20, namely, on a portion opposing the stage 21, an electron beam source 23 serving as electron beam irradiation means is provided, and the electron beam source 23 fully irradiates the resist film formed on the semiconductor substrate 22 with an electron beam 24 of, for example, 5 keV over ten minutes.

On a side of the chamber 20, a gas chromatograph mass spectrometer (GC-MS) 25 serving as gas analysis means for analyzing an outgassing released from the resist film when the resist film on the semiconductor substrate 22 is irradiated by the electron source 23 is provided Thus, the gas chromatograph mass spectrometer 25 can quantitatively or qualitatively analyze a constituent of the outgassing released from the resist film, such as isobutene that is the principal constituent.

What is claimed is:

1. An electron beam aligner comprising:
a substrate holder provided within a chamber for holding a semiconductor substrate on a surface of which a resist film is formed;
electron beam irradiation means for fully irradiating said resist film with an electron beam; and
gas collection means provided on said chamber for collecting an outgassing released from said resist film when irradiated with said electron beam.

2. The electron beam aligner of claim 1, further comprising gas analysis means for analyzing a constituent of said outgassing collected by said gas collection means.

3. An electron beam aligner comprising:
a substrate holder provided within a chamber for holding a semiconductor substrate on a surface of which a resist film is formed;
electron beam irradiation means for fully irradiating said resist film with an electron beam; and
gas analysis means provided on said chamber for analyzing a constituent of an outgassing released from said resist film when irradiated with said electron beam.

4. An outgassing collection method comprising the steps of:
holding, within a chamber, a semiconductor substrate on a surface of which a resist film is formed;
fully irradiating said resist film with an electron beam; and
collecting an outgassing released from said resist film when irradiated with said electron beam.

5. An outgassing analysis method comprising the steps of:
holding, within a chamber, a semiconductor substrate on a surface of which a resist film is formed;
fully irradiating said resist film with an electron beam;
collecting an outgassing released from said resist film when irradiated with said electron beam; and
analyzing a constituent of said collected outgassing.

6. An outgassing analysis method comprising the steps of:
holding, within a chamber, a semiconductor substrate on a surface of which a resist film is formed;
fully irradiating said resist film with an electron beam; and
analyzing a constituent of an outgassing released from said resist film when irradiated with said electron beam.
